(19) United States
(12) Patent Application Publication
(10) Pub. No.: US 2014/0332062 A1
(43) Pub. Date: Nov. 13, 2014

(54) SOLAR CELL APPARATUS

(71) Applicant: LG INNOTEK CO., LTD., Seoul (KR)

(72) Inventor: Ho Gun Cho, Seoul (KR)

(21) Appl. No.: 14/360,907

(22) PCT Filed: Nov. 23, 2012
(86) PCT No.: PCT/KR2012/009989

§ 371 Date: May 27, 2014

(30) Foreign Application Priority Data
Nov. 25, 2011 (KR) 10-2011-0124625

(51) Int. Cl. H01L 31/048

(52) U.S. Cl. CPC H01L 31/048
USPC 136/251

(57) ABSTRACT

A solar cell apparatus according to the embodiment includes a lower substrate; solar cells on the lower substrate; and an upper substrate on the solar cells, wherein at least one of the lower substrate and the upper substrate includes a protrusion extending to a remaining substrate.

### TECHNICAL FIELD

The embodiment relates to a solar cell apparatus.

### BACKGROUND ART

A solar cell (or photovoltaic cell) is a core element in solar power generation to directly convert solar light into electricity.

For example, if the solar light having energy greater than bandgap energy of a semi-conductor is incident into a solar cell having the PN junction structure, electron-hole pairs are generated. As electrons and holes are collected into an N layer and a P layer, respectively, due to the electric field formed in a PN junction part, photovoltage is generated between the N and P layers. In this case, if a load is connected to electrodes provided at both ends of the solar cell, current flows through the solar cell.

Recently, as energy consumption is increased, solar cells to convert the solar light into electrical energy have been developed.

In particular, a CIGS-based solar cell, which is a PN hetero junction apparatus having a substrate structure including a glass substrate, a metallic back electrode layer, a P-type CIGS-based light absorbing layer, a high-resistance buffer layer, and an N-type window layer, has been extensively used.

Various studies and researches have been performed to improve electrical characteristics of the solar cell, such as low resistance and high transmittance.

Stability of power variation as a function of time is requested in a solar cell module. The main reason to request the stability is that moisture is infiltrated into the solar cell, thereby causing damage to the solar cell.

### DISCLOSURE OF INVENTION

### Technical Problem

The embodiment provides a solar cell apparatus which can prevent power reduction caused by the exposure of solar cells to moisture.

### Solution to Problem

According to the embodiment, there is provided a solar cell apparatus including a lower substrate; solar cells on the lower substrate; and an upper substrate on the solar cells, wherein at least one of the lower substrate and the upper substrate comprises a protrusion extending to a remaining substrate.

### ADVANTAGEOUS EFFECTS OF INVENTION

In the solar cell module according to the embodiment, a lower substrate and an upper substrate include a coupling part to prevent solar cells from being exposed to the moisture so that life span and the reliability of devices can be improved.

Further, power reduction according to the lapse of time is minimized so that the amount of annual power generation can be improved.

### BRIEF DESCRIPTION OF DRAWINGS

FIG. 1 is a sectional view showing a solar cell module according to the embodiment;

FIG. 2 is an enlarged sectional view showing a region A of FIG. 1; and

FIGS. 3 to 5 are enlarged sectional views showing a region A of FIG. 1 according to other embodiments.

### BEST MODE FOR CARRYING OUT THE INVENTION

In the description of the embodiments, it will be understood that when a panel, a bar, a frame, a substrate, a groove, or a film, is referred to as being on or under another panel, another bar, another frame, another substrate, another groove, or another film, it can be directly or indirectly on the other panel, the other bar, the other frame, the other substrate, the other groove, the other film, or one or more intervening layers may also be present. Such a position of the layer has been described with reference to the drawings. The size of the elements shown in the drawings may be exaggerated for the purpose of explanation and may not utterly reflect the actual size.

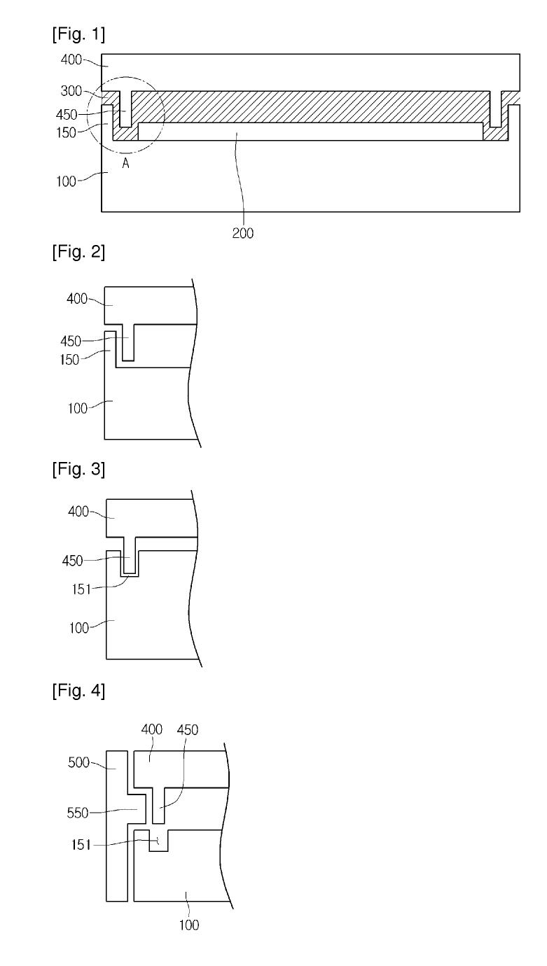

FIG. 1 is a sectional view showing a solar cell module according to the embodiment. FIG. 2 is an enlarged sectional view showing a region A of FIG. 1. FIGS. 3 to 5 are enlarged sectional views showing a region A of FIG. 1 according to other embodiments.

Referring to FIGS. 1 and 2, the solar cell module according to the embodiment includes a lower substrate 100, solar cells 200 formed on the lower substrate 100, a protective layer 300 formed on the solar cells 200, and an upper substrate 400 formed on the protective layer 300.

The lower substrate 100 may be an insulator. The lower substrate 100 may be a glass substrate, a plastic substrate or a metal substrate. In detail, the lower substrate 100 may be a soda lime glass substrate. The lower substrate 100 may be transparent. The lower substrate 100 may be rigid or flexible.

The solar cells 200 may be formed on the lower substrate 100 and have a plate shape.

For example, the solar cells 200 may have a square plate shape. The solar cells 200 may include a back electrode layer, a light absorbing layer, a buffer layer, and a window layer. The solar cells 200 receive solar light and convert the solar light into electric energy.

Frames may be formed at sides of the solar cells 200 to receive the solar cells 200, respectively. For example, the frames may be disposed at four sides of the solar cells 200, respectively. For example, a material used for the frame may include metal such as aluminum.

A protective layer 300 protecting the solar cells 200 may be formed at upper portions of the solar cells 200, respectively. The upper substrate 400 may be formed on the protective layer 300, and may include tempered glass. These components are integrally formed with each other through a lamination process.

The upper substrate 400 and the lower substrate 100 protect the solar cells 200 from an external environment. The upper substrate 400 and the lower substrate 100 may have a multi-layer structure including a layer for preventing moisture and oxygen from being infiltrated, a layer for preventing chemical corrosion, and a layer having insulation characteristics.

Protrusions may be formed at the upper substrate 400 and the lower substrate 100, respectively. In detail, a first protrusion 150 may be formed at the lower substrate 100 and a second protrusion 450 may be formed at the upper substrate 400.

The first protrusion 150 and the second protrusion 450 may vertically overlap with each other or not. When the first protrusion 150 and the second protrusion 450 vertically overlap with each other, a top surface of the first protrusion 150 may make contact with a bottom surface of the second protrusion 450.

The second protrusion 450 may be formed at the same height as that of the first protrusion 150. The top surface of the first protrusion 150 may make contact with a bottom surface of the upper substrate 400, and the bottom surface of the second protrusion 450 may make contact with a tope surface of the lower substrate 100.

The first protrusion 150 and the second protrusion 450 may have a rectangular shape. The first protrusion 150 and the second protrusion 450 may be formed by etching the lower substrate 100 and the upper substrate 400 or by bonding materials to the lower substrate 100 and the upper substrate 400, respectively. When the first protrusion 150 and the second protrusion 450 are formed by etching the lower substrate 100 and the upper substrate 400, the first protrusion 150 and the second protrusion 450 may include glass, respectively.

A side of the second protrusion 450 may make contact with a side of the first protrusion 150, and the side of the second protrusion 450 may be spaced apart from the side of the first protrusion 150 while interposing the protective layer 300 therebetween.

The protective layer 300 is integrated with the solar cells 200 through a lamination process in a state that is disposed at upper portions of the solar cells 200, and prevents corrosion due to infiltration of moisture and protects the solar cells 200 from impact. The protective layer 300 may include a material such as ethylene vinyl acetate (EVA). The protective layer 300 may be further formed at lower portions of the solar cells 200.

The upper substrate 400 may be formed on the protective layer 300. The upper substrate 400 includes tempered glass representing high transmittance rate and a superior damage preventing function. In this case, the tempered glass may include low-iron tempered glass. To improve a scattering effect of light, an inner side of the upper substrate 400 may be embossed.

A bus bar (not shown) makes contact with upper portions of the solar cells 200. For example, the bus bar 300 is disposed on top surfaces of outermost solar cells 200. The bus bar 300 makes direct contact with the top surfaces of the outermost solar cells 200. A bus bar formed at one end of the solar cells 200 and a bus bar formed at an opposite end of the solar cells 200 may have mutually different polarities. For example, when the bus bar formed at the one end of the solar cells 200 acts as an anode, the bus bar formed at the opposite end of the solar cells 200 may act as a cathode.

A junction box (not shown) is electrically connected to the solar cells 200. The junction box may be formed at the bottom surface of the lower substrate 100 and is connected to the bus bar. The junction box includes a bypass diode and may receive a circuit board which is connected to the bus bar and a cable.

The solar cell module according to the embodiment may further include a wire for connecting the bus bar to the circuit board. The cable is connected to the circuit board.

FIG. 3 is a sectional view illustrating a solar cell module according to a second embodiment. As shown, a second protrusion 450 is formed at an upper substrate 400, and a groove 151 in which a second protrusion 450 is inserted is formed at the lower substrate 100. The second protrusion 450 may be partially inserted into the groove 151.

FIG. 4 is a sectional view illustrating a solar cell module according to a third embodiment. In the third embodiment, a second protrusion 450 is formed at the upper substrate 400, a groove 151, into which the second protrusion 450 is partially inserted, is formed at the lower substrate 100, and a side coupling part 500 is coupled with a side of the second protrusion 450. The side coupling part 500 may include a side protrusion 550, and the side protrusion 550 may contact with a top surface of the lower substrate 100, a bottom surface of the upper substrate 400, and a side of the second protrusion 450.

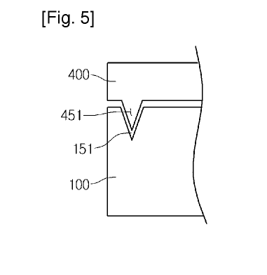

FIG. 5 is a sectional view illustrating a solar cell module according to a fourth embodiment. In the fourth embodiment, the protrusion 451 makes contact with an upper substrate 400 and may have a pyramid shape having a width gradually narrowed downward. The second protrusion 451 may have a tetragonal pyramid shape and a semispherical shape as well as the pyramid shape, and a groove 151, into which the second protrusion 451 is inserted, is formed at the lower substrate 100.

The embodiments of FIGS. 3 to 5 illustrate that a protrusion is formed at the upper substrate 400, but the present invention is not limited thereto. The protrusion may be formed at the lower substrate 100 and a groove into which the protrusion is inserted is formed at the upper substrate. A plurality of protrusions and a plurality of grooves may be formed in at least one end of the substrate.

Any reference in this specification to one embodiment, an embodiment, example embodiment, etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effects such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. A solar cell apparatus comprising:
a lower substrate;
solar cells on the lower substrate; and
an upper substrate on the solar cells,
wherein at least one of the lower substrate and the upper substrate comprises a protrusion extending to a remaining substrate.

2. The solar cell apparatus of claim 1, wherein the protrusion is formed of a material identical to a material of a substrate making contact with the protrusion.

3. The solar cell apparatus of claim 1, further comprising:
a first protrusion at the lower substrate; and
a second protrusion at the upper substrate,
wherein the first protrusion and the second protrusion are not vertically overlapped with each other.

4. The solar cell apparatus of claim 1, further comprising:
a first protrusion at the lower substrate; and
a second protrusion at the upper substrate,
wherein a top surface of the first protrusion makes contact with a bottom surface of the second protrusion.

5. The solar cell apparatus of claim 1, wherein a side of a first protrusion makes contact with a side of a second protrusion.

6. The solar cell apparatus of claim 1, wherein a side of a first protrusion is spaced apart from a side of a second protrusion.

7-8. (canceled)

9. The solar cell apparatus of claim 1, further comprising a side coupling part making contact with a side of the protrusion.

10. The solar cell apparatus of claim 9, wherein the side coupling part comprises a side protrusion, a side of the side protrusion makes contact with the side of the protrusion, a top surface and a bottom surface of the side protrusion make contact with the upper substrate and the lower substrate, respectively.

11. A solar cell apparatus comprising:
a lower substrate;
solar cells on the lower substrate;
an upper substrate on the solar cells;
a protrusion formed on at least one of the lower substrate and the upper substrate; and
a groove, into which the protrusion is inserted, formed at the other substrate.

12. The solar cell apparatus of claim 11, wherein the protrusion is formed of a material identical to a material of the upper substrate.

13. The solar cell apparatus of claim 11, further comprising:
a protective layer between the lower substrate and the upper substrate.

14. The solar cell apparatus of claim 11, wherein a protrusion of the upper substrate makes contact with a bottom surface of the groove of the lower substrate.

15. The solar cell apparatus of claim 11, wherein a side of the protrusion makes contact with a side of the groove.

16. The solar cell apparatus of claim 11, wherein a side of the protrusion is spaced apart from a side of the groove.

17. The solar cell apparatus of claim 11, wherein the protrusion has at least one of a pyramid shape, a tetragonal pyramid shape, and a semispherical shape.

18. The solar cell apparatus of claim 1, wherein the first protrusion and a second protrusion are formed at the same height.

19. The solar cell apparatus of claim 11, wherein the upper substrate comprises a protrusion vertically overlapping with the groove.

20. The solar cell apparatus of claim 11, further comprising a side coupling part making contact with a side of the protrusion.

21. The solar cell apparatus of claim 20, wherein a height of the side coupling part and sum of a height of the upper substrate and the lower substrate are the same.
